(19) United States
(12) Patent Application Publication
(10) Pub. No.: US 2004/0029401 A1
(43) Pub. Date: Feb. 12, 2004

(54) Organic insulating film forming method, semiconductor device manufacture method, and TFT substrate manufacture method

(75) Inventors: Hiroyasu Matsugai, Kawasaki (JP); Masanobu Ikeda, Kawasaki (JP); Takahiro Kimura, Kawasaki (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU LIMITED, Kawasaki (JP)

(21) Appl. No.: 10/632,820

(22) Filed: Aug. 4, 2003

(30) Foreign Application Priority Data
Aug. 6, 2002 (JP) 2002-228088

(51) Int. Cl. H01L 51/40; H01L 21/00; H01L 21/84; H01L 21/31; H01L 21/469

(52) U.S. Cl. 438/780; 438/99; 438/781; 438/149

(57) ABSTRACT

Solution is coated on a substrate, the solution being obtained by dissolving monomer or oligomer in solvent, the monomer or oligomer having a triple-bond of two carbon atoms and being used as a raw material of organic insulating material. Ultraviolet rays are irradiated upon the monomer or oligomer coated on the substrate to conduct polymerization and form an insulating film made of the organic insulating material. An insulating film made of high quality organic insulating material can be formed at a relatively lot temperature.

### CROSS REFERENCE TO RELATED APPLICATION

This application is based on Japanese Patent Application No. 2002-228088, filed on Aug. 6, 2002, the entire contents of which are incorporated herein by reference.

### BACKGROUND OF THE INVENTION

A) Field of the Invention

The present invention relates to an organic insulating film forming method and a semiconductor device manufacture method, and more particularly to a method of forming an organic insulating film by coating solution on a substrate and polymerizing it, the solution being obtained by dissolving monomer or oligomer in solvent, the monomer or oligomer being used as raw material of the organic insulating film, and to a method of manufacturing a semiconductor device and a thin film transistor (TFT) substrate having such an organic insulating film.

B) Description of the Related Art

With recent miniaturization and high integration of semiconductor integrated circuit devices, an interlayer insulating film made of low dielectric constant organic insulating material has been paid attention. According to the method disclosed in JP-A-63-144525, hydrogen silsesquioxane resin solution is coated on the surface of a substrate on which electronic components are formed, and solvent is vaporized. Thereafter, heat treatment is performed at 150 to 1000° C. to form an insulating film. In general, final heat treatment is performed in a vertical batch type heating furnace for about 1 hour at a temperature of 400° C. or higher.

If a semiconductor integrated circuit device has multilevel wiring layers formed by a dual damascene method, heat treatment at such a high temperature and for a long time may often result in conduction failure because of stress migration in a via hole interconnecting upper and lower layers. It is also known that leak current during a standby state of a semiconductor active component is largely dependent upon a thermal load during the manufacture. As a thermal load becomes large, leakage current during the standby state increases.

In order to reduce a power consumption of a liquid crystal display device, it is desired to lower the dielectric constant of an insulating film. However, it is impossible to perform heat treatment at a temperature higher than the melting point of a glass substrate.

Polymerization of organic polymer is largely dependent upon a process temperature. Even if the heat treatment temperature is lowered and the process time is shortened, a film having a desired cross-linking ratio and a high quality cannot be formed.

### SUMMARY OF THE INVENTION

An object of this invention is to provide a method of forming an organic insulating film at a relatively low temperature, the organic film being made of high quality organic insulating material.

Another object of the invention is to provide a method of manufacturing a semiconductor device and a TFT substrate having a high quality organic insulating film formed at a relatively low temperature.

According to one aspect of the present invention, there is provided a method of forming an organic insulating film, comprising steps of: coating solution on a substrate, the solution being obtained by dissolving monomer or oligomer in solvent, the monomer or oligomer having a triple-bond of two carbon atoms and being used as a raw material of organic insulating material; and irradiating ultraviolet rays upon the monomer or oligomer coated on the substrate to conduct polymerization and form an insulating film comprising the organic insulating material.

According to another aspect of the present invention, there is provided a method of manufacturing a semiconductor device, comprising steps of: (a) coating solution on a substrate formed with a semiconductor active element on a surface of the substrate, the solution being obtained by dissolving monomer or oligomer in solvent, the monomer or oligomer being used as a raw material of organic insulating material; and (b) irradiating ultraviolet rays upon the monomer or oligomer coated on the substrate to conduct polymerization and form an insulating film comprising the organic insulating material.

According to another aspect of the present invention, there is provided a method of manufacturing a TFT substrate comprising steps of: forming, on a surface of a transparent substrate, a plurality of thin film transistors disposed in a matrix shape, a gate wiring line corresponding to each row of the thin film transistors and connected to gate electrodes of thin film transistors of the corresponding row, and a source wiring line corresponding to each column of the thin film transistors and connected to source electrodes of thin film transistors of the corresponding column; coating solution on the transparent substrate, covering the thin film transistors, the gate wiring lines and the source wiring lines, the solution being obtained by dissolving monomer or oligomer in solvent, the monomer or oligomer being used as a raw material of organic insulating material; irradiating ultraviolet rays upon the monomer or oligomer coated on the transparent substrate to conduct polymerization and form an insulating film comprising the organic insulating material; and forming pixel electrodes on the insulating film, each of the pixel electrodes corresponding to each of the thin film transistors and connected to a drain region of corresponding thin film transistor.

Polymerization under ultraviolet rays can achieve a desired cross-linking ratio at a relatively low temperature.

### BRIEF DESCRIPTION OF THE DRAWINGS

FIG. 1 is a diagram showing a molecular structure of a molecular model used by simulation.

FIG. 2 is a schematic cross sectional view of a baking system to be used by a method of forming an organic insulating film according to a first embodiment of the invention.

FIG. 3 is a graph showing the relation between a baking time and a cross-linking ratio, using a baking temperature as a parameter.

FIGS. 4A to 4E are cross sectional views of a substrate illustrating a method of manufacturing a semiconductor device according to a second embodiment.

FIG. 5 is a plan view of a liquid crystal display device according to a third embodiment.

FIG. 6 is a cross sectional view of a TFT used by the liquid crystal display device of the third embodiment.

### DESCRIPTION OF THE PREFERRED EMBODIMENTS

Known raw materials of organic insulating materials are SiLK (registered trademark) of the Dow Chemical Company and GX-3 (registered trademark) of Honeywell International Inc. These raw materials contain monomer or oligomer having a triple-bond of two carbon atoms. Polymerization is performed at the triple-bond to form organic insulating polymer.

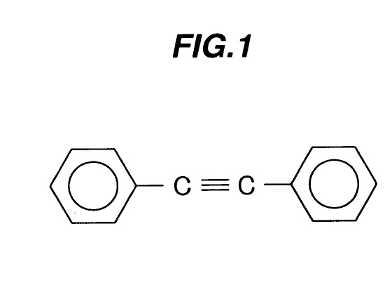

FIG. 1 shows a molecular model of a part of a molecule of a raw material of organic insulating polymer. Two benzene rings are coupled via triple-bonded two carbon atoms. Two benzene rings on the same plane (in a parallel state) and two benzene rings whose planes are perpendicular (in a perpendicular state) take stable energy states. An energy difference calculated by a semiempirical molecular orbit method was about 0.42 kcal/mol. Benzene rings are rotated almost freely by a thermal energy of about a room temperature. Namely, the molecular model shown in FIG. 1 can take the parallel state, the perpendicular state and an intermediate state therebetween, respectively at the room temperature.

An ultraviolet absorption spectrum of this molecular model was obtained by a molecular orbit method. It was found that in the parallel state of benzene rings, a large absorption peak appeared near at a wavelength of 305 nm and that in the perpendicular state of benzene rings, a large absorption peak appeared near at a wavelength of 245 nm. Since this molecular model can take the parallel state, perpendicular state and intermediate state at the room temperature, it can be considered that an absorption peak appears spreading from the wavelength of 245 nm to the wavelength of 305 nm at the room temperature.

Since the actual compositional raw material of organic insulating material has a complicated structure more than this molecular model, it can be considered that the absorption peak becomes broader. It can be considered that polymerization can be promoted by irradiating ultraviolet rays having a wavelength of 200 to 350 nm to the compositional raw material of organic insulating polymer.

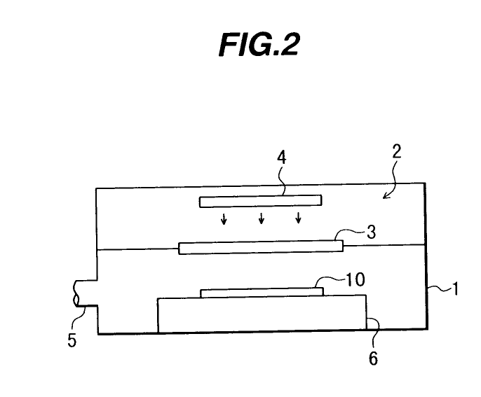

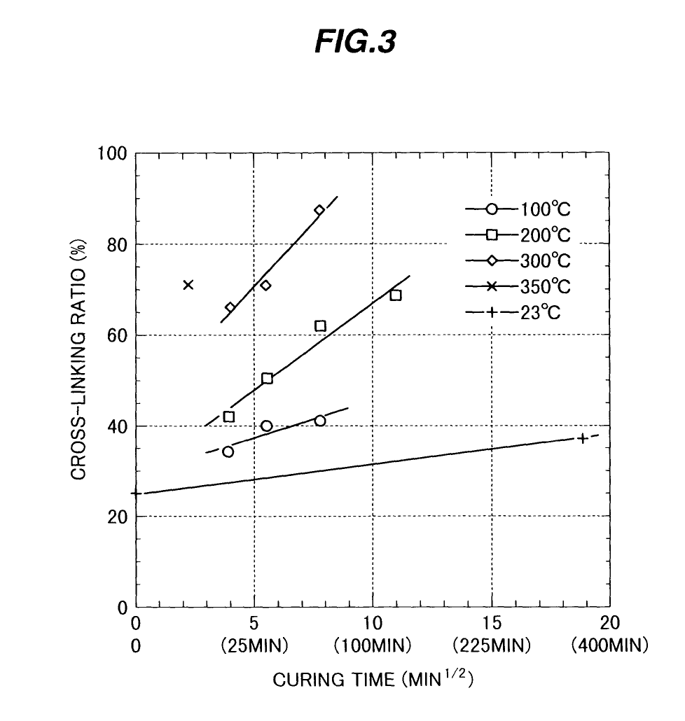

Next, with reference to FIGS. 2 and 3, description will be given on a method of forming an organic insulating film according to the first embodiment of the invention.

SiLK (registered trademark) of the Dow Chemical Company as the compositional raw material of organic insulating material is coated on a substrate by a spin coating method. An average molecular weight of the compositional raw material before coating is 8000 to 10000. Pre-baking is performed for 90 seconds at 320° C. by using a hot plate to evaporate main solvent. This prebaking temperature is an optimum temperature determined from the boiling point of 156° C. of cyclohexanone as the main solvent, the boiling point of 206° C. of γ-butyrolactone as the solvent, and reaction of coupling material used for increasing adhesion between an organic insulating film and an underlying surface.

FIG. 2 is a schematic cross sectional view of a baking system. A substrate support 6 is arranged in a vacuum chamber 1, and a substrate 10 is placed on the substrate support. A heater is housed in the substrate support 6 to heat the substrate 10 on the substrate support. The inside of the vacuum chamber 1 is evacuated from an air discharge pipe 5.

An upper opening of the vacuum chamber 1 is air-tightly sealed by a lamp room 2. A deep ultraviolet ray lamp 4 is mounted in the lamp chamber 2. A quartz glass plate 3 is mounted on a partition between the inner cavity of the lamp room 2 and the inner cavity of the vacuum chamber 1. Ultraviolet rays irradiated from the deep ultraviolet lamp 4 transmit through the quartz glass plate 3 and are irradiated upon the surface of the substrate 10 disposed in the vacuum chamber 1.

The substrate 10 coated with raw material solution of organic insulating material and pre-baked is placed on the substrate support 6 of the baking system shown in FIG. 2. The inside of the vacuum chamber 1 is evacuated, and while the substrate is heated to a predetermined temperature, ultraviolet rays are irradiated upon the surface of the substrate 10. Irradiation of ultraviolet rays and substrate heating promote polymerization of organic insulating material.

FIG. 3 is a graph showing the relation between a baking time and a cross-linking ratio, using a baking temperature as a parameter. The abscissa of the graph shown in FIG. 3 represents a root of a baking time in the unit of “min^{1/2}” and the ordinate represents a cross-linking ratio in the unit of “%”. A circle, a rectangle, a rhomboid, a x mark and a +mark shown in FIG. 3 represent cross-linking ratios of baked samples whose substrate temperatures were set to 100° C., 200° C., 300° C., 350° C. and 23° C., respectively. The power densities of ultraviolet rays at the surfaces of the substrates 10 of the samples are all 2.1 mW/cm². The cross-linking ratio can be estimated from Raman peaks of the triple-bond of two carbon atoms and aromatic bond measured by a Raman spectroscopic method.

A cross-linking ratio of an organic insulating film formed by a conventional baking method (heat treatment for 30 minutes at a substrate temperature of 400° C. without irradiation of ultraviolet rays) is about 70%. In this embodiment, since both substrate heating and ultraviolet irradiation are performed, the cross-linking ratio can be increased to 70%, for example, by baking for about 5 minutes at a substrate temperature of 350° C., by baking for about 25 minutes at a substrate temperature of 300° C., or by baking for about 100 minutes at a substrate temperature of 200° C.

It is preferable to set the cross-linking ratio to 60% or higher from the viewpoint of adhesion, degassing, stresses and the like of an organic insulating film. By using both substrate heating and ultraviolet irradiation, it is possible to achieve the cross-linking ratio of 60% or higher without raising the substrate temperature to about 400° C.

In the first embodiment, the substrate 10 is placed in the baking system shown in FIG. 2 after the pre-baking. Instead, pre-baking and main baking may be performed continuously by using the baking system shown in FIG. 2. In this case, a throughput can be improved.

In the first embodiment, although the power density of ultraviolet rays at the substrate surface is set to 2.1 mW/cm², the power density is not limited only thereto. It can be expected that as the power density is raised, the cross-linking ratio is increased. In order to achieve a sufficient cross-linking ratio without lowering a throughput, it is preferable to set the power density of ultraviolet rays to 2.1 mW/cm² or higher.

If oxygen is mixed during polymerization, oxygen atoms are bonded to an active portion where the triple-bond of two carbon atoms is cut. From this reason, it is preferable that the inside of the vacuum chamber 1 is maintained in the vacuum state of 0.13 Pa (1×10⁻³ torr) during the baking period. Instead of the vacuum state, an inert gas atmosphere having an oxygen density of 100 ppm or lower may be used.

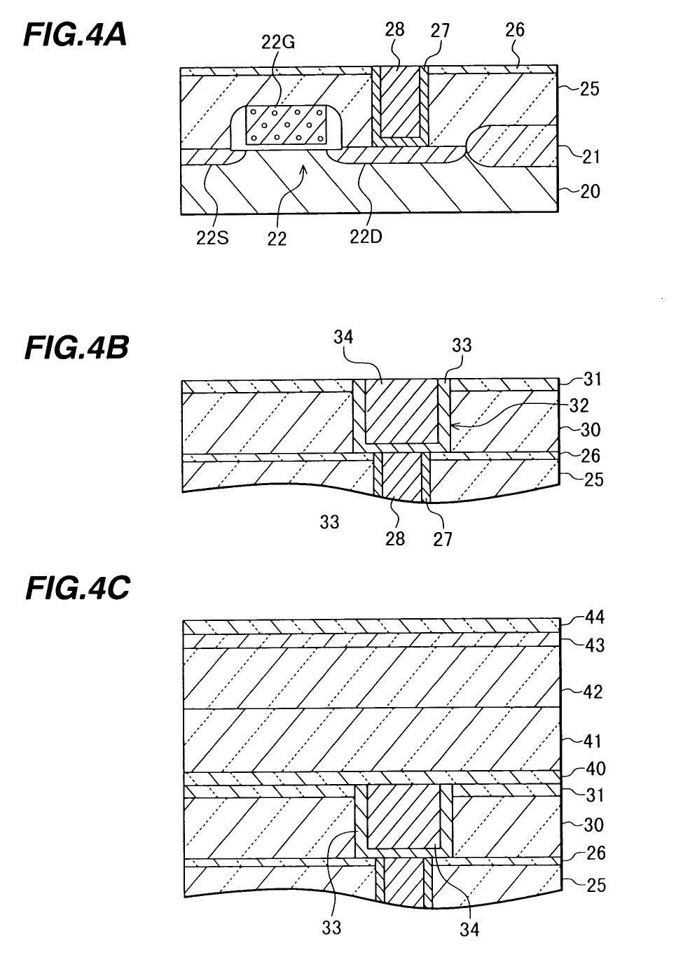

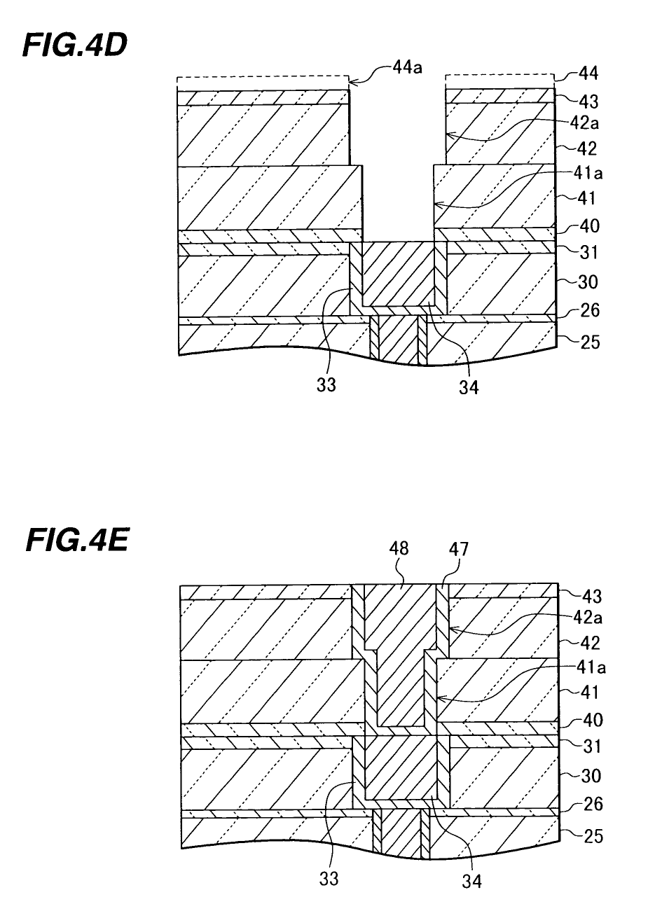

Next, with reference to FIGS. 4A to 4E, description will be given on a method of manufacturing a semiconductor device according to the second embodiment of the invention.

As shown in FIG. 4A, active regions are defined by forming an element separation insulating film 21 in the surface layer of a silicon semiconductor substrate 20 by local oxidation of silicon (LOCOS) or shallow trench isolation (STI). A MOSFET 22 is formed in the active region by a wellknown method. MOSFET 22 comprises a source region 22S, a drain region 22D and a gate electrode 22G.

On the semiconductor substrate 20, a first-layer interlayer insulating film 25 made of phosphosilicate glass (PSG) is formed by chemical vapor deposition (CVD). On the first-layer interlayer insulating film 25, an etching stopper layer 26 made of silicon nitride is formed by CVD. A contact hole is formed through the etching stopper layer 26 and interlayer insulating film 25, the contact hole reaching the drain region 22D.

A TiN layer and a tungsten layer are deposited and unnecessary TiN layer and tungsten layer are removed by chemical mechanical polishing (CMP) to leave a barrier metal layer 27 of TiN and a conductive plug 28 of tungsten in the contact hole.

The processes up to the state shown in FIG. 4B will be described.

In FIGS. 4B to 4E, only the layers upper than the first-layer interlayer insulating film 25 are drawn. On the etching stopper layer 26, an interlayer insulating film 30 is formed, having a thickness of 150 nm and made of organic insulating material by the method of the first embodiment. On the interlayer insulating film 30, a cap film 31 is formed having a thickness of 250 nm and made of silicon oxide.

A wiring trench 32 is formed in the cap film 31 and interlayer insulating film 30 by reactive ion etching (RIE) using CF₄ and CHF₃. The conductive plug 28 is exposed on the bottom of the wiring trench 32. A barrier metal layer 33 having a thickness of 15 nm and made of TaN is formed on the inner surface of the wiring trench 32 and on the surface of the cap film 31, and on the surface of the barrier metal layer 33, a Cu seed layer having a thickness of 130 nm is formed. The Cu seed layer is subjected to electroplating to form a Cu layer having a thickness of 970 nm. Thereafter, the TaN layer and Cu layer excepting those in the wiring trench 32 are removed by CMP. With the above processes, a copper wiring 34 is formed.

As shown in FIG. 4C, on the wiring layer with the copper wiring 34, an etching stopper film 40 of silicon nitride having a thickness of 70 nm, a via layer insulating film 41 of silicon oxide having a thickness of 280 nm, a wiring layer insulating film 42 of organic insulating material having a thickness of 150 nm, a cap film 43 of silicon oxide having a thickness of 250 nm and a hard mask film 44 of silicon nitride having a thickness of 100 nm are sequentially formed. The wiring layer insulating film 42 of organic insulating material is formed by the method of the first embodiment.

The processes up to the state shown in FIG. 4D will be described. An opening 44a corresponding to a wiring pattern is formed through the hard mask film 44 by RIE using CHF₃. Next, by using as a mask a resist film having an opening corresponding to a via hole for the connection to the underlying wiring 34, the cap film 43, wiring layer insulating film 42 and via layer insulating film 41 are etched by RIE using C₅F₈, NH₃ and H₂ while changing gas compositions during etching, until the etching stopper film 40 is exposed. A via hole 41a is therefore formed. After the resist mask is removed, by using as a mask the hard mask film 44 with the opening corresponding to the wiring pattern, the wiring layer insulating film 42 is etched to its bottom by RIE using NH₃ to form a wiring trench 42a. The hard mask film 44 and the etching stopper film 40 exposed on the bottom of the via hole 41a are removed by RIE using CH₂F₂.

The processes up to the state shown in FIG. 4E will be described. The inner surfaces of the wiring trench 42a and via hole 41a and the upper surface of the cap film 43 are covered with a TaN layer having a thickness of 15 nm. A Cu seed layer having a thickness of 130 nm is formed and subjected to electroplating to form a Cu layer having a thickness of 970 nm. The TaN layer and Cu layer are subjected to CMP to leave a barrier metal layer 47 and a copper wiring 48 in the wiring trench 42a and via hole 41a.

On the Cu wiring 48, a multilevel Cu wiring structure is formed by a dual damascene method similar to the method described above. Since the insulating film made of organic insulating material is formed by heat treatment at about 350° C., it is possible to avoid conduction failure at the interlayer connection region in the via hole formed by the dual damascene method.

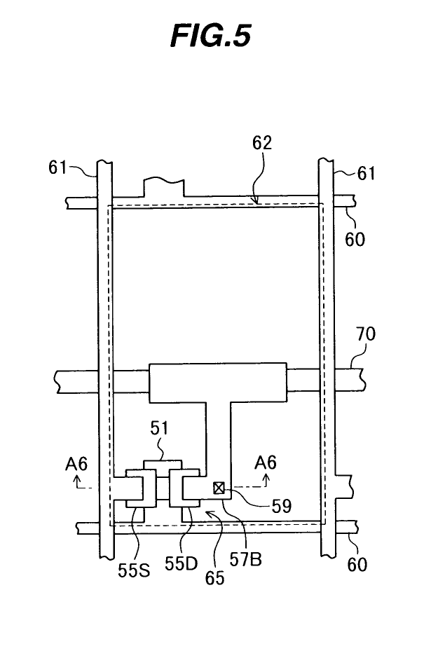

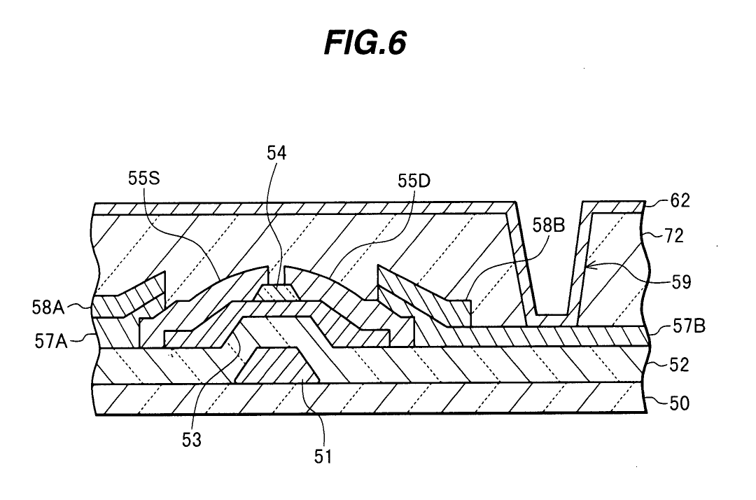

Next, with reference to FIGS. 5 and 6, description will be given on a method of manufacturing a thin film transistor (TFT) substrate according to the third embodiment.

FIG. 5 is a plan view of one pixel of a liquid crystal display device of the third embodiment using TFTs. A plurality of gate wiring lines 60 are disposed in the horizontal (row) direction in FIG. 5 at an equal pitch, and a plurality of source wiring lines 61 are disposed in the vertical (column) direction at an equal pitch. The gate and source wiring lines 60 and 61 are electrically insulated at cross areas therebetween. A scan signal is applied to the gate wiring line 60, and an image signal is applied to the source wiring line 61.

A transparent pixel electrode 62 is disposed in an area surrounded by adjacent two gate wiring lines 60 and adjacent two source wiring lines 61. The outer peripheral area of the pixel electrode 62 overlaps the partial areas of the gate and source wiring lines 60 and 61. An additional capacitor wiring line 70 is disposed between adjacent two gate wiring lines 60. A fixed voltage is applied to the additional capacitor wiring line 70.

A TFT 65 is disposed in each cross area between the gate wiring line 60 and source wiring line 61. The gate electrode 51 of TFT 65 branches from the corresponding gate wiring line 60. The source electrode 55S of TFT 65 is connected to the corresponding source wiring line 61.

The drain electrode 55D of TFT 65 is connected to a connection electrode 57B made of transparent conductive material. The connection electrode 57B is connected to the pixel electrode 62 via a contact hole 59. The connection electrode 57B extends to the area where the additional capacitor wiring line 70 is disposed, to thereby form an additional capacitor together with the additional capacitor wiring line 70.

FIG. 6 is a cross sectional view taken along one-dot chain line A6-A6 shown in FIG. 5. With reference to FIG. 6, a method of manufacturing a TFT substrate will be described.

On the surface of a glass substrate 50, gate electrodes 51 of polysilicon are formed. The gate electrode 51 may be made of aluminum, chromium or gold. At the same time when the gate electrodes 51 are formed, the gate wiring lines 60 and additional capacitor wiring lines 70 shown in FIG. 5 are formed. A gate insulating film 52 of silicon oxide (or silicon nitride) is formed on the glass substrate 50, the gate insulating film covering the gate electrode 51. On the gate insulating film 52, a semiconductor layer 53 is formed on the gate insulating film 52, the semiconductor layer 53 overriding the gate electrode 51.

A channel protection film 54 of silicon nitride is formed on the surface of the semiconductor layer 53 above the gate electrode 51. A source electrode 55S and a drain electrode 55D respectively made of aluminum (or chromium, gold, nickel or the like) are formed covering the surface of the semiconductor layer 53 on both sides of the channel protection film 54.

The processes described above can be performed by well known film forming method, photolithography and etching.

A transparent conductive film of indium tin oxide (ITO) or the like and a metal film of aluminum are formed on the gate insulating film by sputtering, the transparent conductive film and metal film covering the source electrode 55S and drain electrode 55D. By pattering the metal film, a source connection lead 58A and a drain connection lead 58B are formed, and by pattering the transparent conductive film, a connection electrode 57B and a source connection lead 57A are formed. At the same time, the source wiring lines 61 having the two-layer structure of the transparent conductive film and metal film are formed.

The connection electrode 57B is therefore connected to the drain electrode 55D and the source connection lead 57A is therefore connected to the source electrode 55S.

An interlayer insulating film 72 made of organic insulating material and having a thickness of 15 μm is formed covering the connection electrode 57B, source connection leads 57A and 58A and drain connection lead 58B. The interlayer insulating film 72 is formed by the method of the first embodiment. A contact hole 59 for exposing a partial surface of the connection electrode 57B is formed through the interlayer insulating film 72. The interlayer insulating film 72 can be etched by RIE using NH₃ and H₂. By using photoresist which contains silicon elements as the material of an etching mask, an etching selection ratio between the interlayer insulating film 72 and etching mask can be made large.

A pixel electrode 62 of ITO is formed on the interlayer insulating film 72. The pixel electrode 62 is connected to the connection electrode 57B via the contact hole 59.

In the TFT substrate of a liquid crystal display device shown in FIGS. 5 and 6, the interlayer insulating film 72 of organic insulating material is disposed under the pixel electrode 62. Therefore, even if the pixel electrode 62 is superposed upon the gate wiring line 60, source wiring line 61 and TFT 65 as viewed in the substrate in-plane, the electrical influence of each wiring line and TFT can be mitigated. It is therefore possible to improve an aperture ratio of the liquid crystal display device. It is also possible to suppress the generation of discrimination because the pixel electrode 62 shields the electric field to be caused by electric signals applied to the gate wiring line 60 and source wiring line 61.

Since the interlayer insulating film 72 is made of low dielectric constant organic insulating material, an electrostatic capacitance between the pixel electrode 62 and each of the wiring lines 60 and 61 can be made small. Crosstalk and the like to be caused by the capacitance between the pixel electrode and each wiring line can therefore be reduced. Blue light may be slightly absorbed in the regions of the interlayer insulation film without cross-linking. This absorption amount is very small and the visual sensitivity of a human being relative to blue light is lower than that of other colors. Therefore, a problem of the display quality hardly occurs.

The present invention has been described in connection with the preferred embodiments. The invention is not limited only to the above embodiments. It is apparent that various modifications, improvements, combinations, and the like can be made by those skilled in the art.

What we claim are:

1. A method of forming an organic insulating film, comprising steps of:
coating solution on a substrate, the solution being obtained by dissolving monomer or oligomer in solvent, the monomer or oligomer having a triple-bond of two carbon atoms and being used as a raw material of organic insulating material; and
irradiating ultraviolet rays upon the monomer or oligomer coated on the substrate to conduct polymerization and form an insulating film comprising the organic insulating material.

2. A method of forming an organic insulating film according to claim 1, wherein the ultraviolet rays contain components having a wavelength of 200 to 350 nm.

3. A method of forming an organic insulating film according to claim 1, wherein the ultraviolet rays are irradiated to the substrate in the ambient of oxygen content less than 100 ppm.

4. A method of manufacturing a semiconductor device, comprising steps of:
(a) coating solution on a substrate formed with a semiconductor active element on a surface of the substrate, the solution being obtained by dissolving monomer or oligomer in solvent, the monomer or oligomer being used as a raw material of organic insulating material; and
(b) irradiating ultraviolet rays upon the monomer or oligomer coated on the substrate to conduct polymerization and form an insulating film comprising the organic insulating material.

5. A method of manufacturing a semiconductor device according to claim 4, wherein the monomer or oligomer used as the raw material of organic insulating material has triple-bonds of two carbon atoms and polymerization is conducted at the triple-bonds in the step (b).

6. A method of manufacturing a semiconductor device according to claim 5, wherein the ultraviolet rays contain components having a wavelength of 200 to 350 nm.

7. A method of manufacturing a semiconductor device according to claim 4, wherein the ultraviolet rays are irradiated in the step (b) while the substrate is heated.

8. A method of manufacturing a semiconductor device according to claim 7, wherein the substrate is heated in the step (b) at a temperature not higher than 350° C.

9. A method of manufacturing a TFT substrate comprising steps of:
forming, on a surface of a transparent substrate, a plurality of thin film transistors disposed in a matrix shape, a gate wiring line corresponding to each row of the thin film transistors and connected to gate electrodes of thin film transistors of the corresponding row, and a source wiring line corresponding to each column of the thin film transistors and connected to source electrodes of thin film transistors of the corresponding column;
coating solution on the transparent substrate, covering the thin film transistors, the gate wiring lines and the source wiring lines, the solution being obtained by dissolving monomer or oligomer in solvent, the monomer or oligomer being used as a raw material of organic insulating material;
irradiating ultraviolet rays upon the monomer or oligomer coated on the transparent substrate to conduct polymerization and form an insulating film comprising the organic insulating material; and
forming pixel electrodes on the insulating film, each of the pixel electrodes corresponding to each of the thin film transistors and connected to a drain region of corresponding thin film transistor.

10. A method of manufacturing a TFT substrate according to claim 9, wherein as viewed along a line parallel to a normal to the surface the transparent substrate, an outer periphery of the pixel electrode is superposed upon the gate wiring line and the source wiring line.

11. A method of manufacturing a TFT substrate according to claim 9, wherein the monomer or oligomer has triple-bonds of two carbon atoms and polymerization is conducted at the triple-bonds in the step of conducting polymerization.
